(19) United States
(12) Patent Application Publication
(10) Pub. No.: US 2025/0141087 A1
(43) Pub. Date: May 1, 2025

(54) ANTENNA INLAY FOR A DOCUMENT AND DOCUMENT WITH SUCH AN ANTENNA INLAY

(71) Applicant: LINXENS HOLDING, Mantes la Jolie (FR)

(72) Inventors: Sunthari WANITTIYAUBON, Phra Nakhon Si Ayutthaya (TH); Khiengkrai KHUSUWAN, Phra Nakhon Si Ayutthaya (TH); Niwat SOMKHANTEE, Phra Nakhon Si Ayutthaya (TH); Thaweechai MAKHAM, Phra Nakhon Si Ayutthaya (TH)

(21) Appl. No.: 18/692,135

(22) PCT Filed: Jun. 29, 2022
(86) PCT No.: PCT/IB2022/000391

§ 371 Date: Mar. 14, 2024

(30) Foreign Application Priority Data
Oct. 28, 2021 (WO) PCT/IB2021/000747

(51) Int. Cl. H01Q 1/22; H01Q 7/00; H05K 1/02; H05K 1/18

(52) U.S. Cl. CPC H01Q 1/2225; H01Q 7/00; H05K 1/0277; H05K 1/189; H05K 2201/10098

(57) ABSTRACT

In various aspects, the present disclosure provides an antenna inlay for a document and a document with such an antenna inlay. In some embodiments herein, an antenna inlay for a document comprises an inlay substrate foldable along a folding line, and an antenna formed one or embedded into the inlay substrate. The antenna comprises a first antenna portion having at least one first antenna portion routed outside the folding line and at least one conductive bridging portion routed to extend across the folding line. The at least one conductive bridging portion is electrically connected with an associated one of the at least one first antenna portion and the at least one conductive bridging portion is routed at the folding line so as to cross the folding line at an inclination angle unequal to 90°.

### RELATED APPLICATION

This application is a 35 U.S.C. § 371 application of and claims priority from PCT Application Serial No. PCT/IB2022/000391, entitled “Antenna Inlay for a Document and Document with Such an Antenna Inlay,” filed on Jun. 29, 2022, the contents of which are hereby incorporated herein in their entirety by this reference.

### FIELD OF THE INVENTION

The present invention relates to an antenna inlay for a document and to a document with such an antenna inlay. In particular, the invention concerns foldable inlays and foldable documents.

### BACKGROUND ART

Increasingly, documents carrying sensitive information such as security documents of the identity type, identity cards, smart cards and the like, include an electronic circuit with contactless reading ability. For example, such a document may be implemented as a foldable document such as an identity document booklet like a passport or the like. Often, the electronic circuit of such documents comprises an electronic module or chip connected to an inductive or capacitive antenna such that this type of document can be used to store personal data concerning civil status and biometric data, as well as administrative data in digital form, bank data, access data etc.

When security documents are to be checked, e.g., for verification in a validity check or electronically reading information provided by such a document, the stored data is read by a receiving device or reader via remote electric coupling between the electronic circuit of a security document, with the electronic circuit implementing the electronic function of a transponder, and the reader. Using contactless technology for reading information of security documents makes it important to inhibit unintended reading of the identity document, particularly, avoiding reading of the security document without the knowledge of the holder of the security document. In practice, a contactless technology in security documents may be more acceptable when the authorization to read data stored in the document remains under the control of the document holder.

An existing solution to the issue of unintended contactless reading of the document is the use of a passive element for masking the antenna of the security document, such as in terms of an electromagnetic shielding bag. In practice, the security document to be protected from unintentional reading is placed in the electromagnetic shielding bag and only removed from the electromagnetic shielding bag when the holder of the security document intends to present the security document to a reading device.

In the usage of a passive element for masking the antenna, such as an electromagnetic shielding bag, the additional task of removing the security document from the shielding bag when presenting the security document is required. This additional task may impose a significant inconvenience for the holder of the security document and, therefore, may be considered as a suboptimal solution, especially in the mass market where users frequently forego such inconveniences.

A known solution is presented in document US 2007/0164866 A1 which shows a security document having a contactless chip with data masking. The security document comprises a transponder of an electronic module connected to an antenna placed on a given surface of a first part of the document, wherein the transponder serves to remotely communicate with a reader via an electromagnetic coupling. Furthermore, the security document comprises a passive masking element for the antenna, wherein the passive masking element is supported by a second part of the document and can move relative to the first part. The masking element is capable of interfering with the coupling between the transponder and the reader for rendering the reading of the document impossible when the second part is in a predetermined position that corresponds to a closed position of the document.

In addition to security related issues of documents with contactless contacting or communication features, it is further to be ensured that the design these documents fulfills reliability requirements such as a certain minimum lifetime of a document during normal usage of the document. In the case of a foldable document having an antenna for contactless communication, the wire of the antenna may cross a folding line of the document whereby repeated opening and closing of the document imposes repeated mechanical strain onto the wire of the antenna leading to breakage of the wire, thereby considerably impairing the lifetime of the document.

In view of the above-discussed background art, it is desirable to provide an antenna inlay for a foldable document with contactless communication features, the document having a shielding function that only allows an authorized reader to read the document while unintended reading by others than the authorized reader is inhibited, and an improved lifetime.

### SUMMARY

The above-indicated problems and objects are solved by an antenna inlay for a document in accordance with independent claim 1 and by a document with such an antenna inlay in accordance with claim 21. More advantageous embodiments are defined in the dependent claims 2 to 20 and 22 to 23.

In various aspects and embodiments of the present invention, an antenna inlay for a document is provided, while in other aspects and embodiments, a document with such an antenna inlay is provided. In embodiments herein, the antenna inlay for a document may be an antenna inlay for a foldable document such that the antenna inlay is foldable along a folding line. A document may be a document carrying electronic information such as a security document of the identity type, identity card, smart card and the like, including an electronic circuit with contactless reading ability.

In a first aspect of the present disclosure, an antenna inlay for a document is provided. In accordance with illustrative embodiments herein, the antenna inlay comprises an inlay substrate foldable along a folding line, and an antenna formed on or embedded into the inlay substrate. The antenna comprises a first antenna portion, e.g., having at least one first antenna track portion, routed outside the folding line and at least one conductive bridging portion routed to extend across the folding line. The at least one conductive bridging portion is electrically connected with the first antenna portion, e.g., having at least one bridging track line connected with an associated one of the at least one first antenna track portion. The at least one conductive bridging portion is routed at the folding line so as to cross the folding line at an inclination angle unequal to 90°. An accordingly inclined conductive bridging portion is particularly advantageous in reducing mechanical strain imposed on the conductive bridging portion at the folding line when subjecting the foldable antenna inlay to folding and unfolding operations when compared to antennas with track portions substantially perpendicularly crossing the folding line. An inclination angle which increasingly deviates from 90° results in an increasing component of the conductive bridging portion extending parallel to the folding line and thus having an increasing component parallel to a maximum bending stress line, thereby reducing tension in the conductive bridging portion across the folding line and prolonging fatigue to a break period. In a preferred example herein, the at least one conductive bridging portion may be inclined so as to substantially be as much parallel to the folding line as possible, e.g., deviating from the folding line by at most 45° or at most 30° or at most 25°. In a special illustrative example herein, the at least one conductive bridging portion may deviate from the folding line by about 16°. An antenna track portion represents a continuous line portion of the antenna portion routed outside a hinge region. Herein, the hinge region of the inlay substrate represents a region of the inlay substrate which comprises a folding line and which becomes deformed upon folding the inlay substrate, while regions or portions of the inlay substrate outside the hinge region are substantially not deformed when folding the inlay substrate. In some illustrative examples herein, the at least one first antenna track portion may be routed outside the folding line at least in a substantially semicircular shape. Herein and in the following, a substantially semicircular shape is understood as representing a shape that is a semicircular shape or a shape resembling a shape of “u” or “c” or may be obtained by a continuous deformation of a semicircle. Half of a rectangular planar antenna coil with rounded corners is considered as being of a substantially semicircular shape.

In some illustrative embodiments of the first aspect, the at least one conductive bridging portion may be routed linearly at a constant inclination relative to the folding line such that an advantageous inclination of the conductive bridging portion relative to the folding line is ensured. In some illustrative example herein, the at least one conductive bridging portion may couple to the first antenna portion outside the hinge region via a curved routing portion, such as a curved routing portion of a semicircular shape. The curved routing portion allows to elastically compensate mechanical strain acting along a direction perpendicular to the folding line. Herein, the at least one conductive bridging portion may extend across the entire hinge region with constant inclination relative to the folding line.

In some other illustrative embodiments of the first aspect and alternative to the above-described illustrative embodiments, the at least one conductive bridging portion is routed in a zig-zag or meander-like or triangular or sawtooth or sinusoidal shape relative to the folding line. An accordingly formed conductive bridging portion allows to further reduce mechanical strain due to a mechanical spring effect realized by the zig-zag or meander-like or triangular or sawtooth or sinusoidal shape across the folding line. In case that two or more conductive bridging portions are provided, different types of conductive bridging portions may be employed such as at least one conductive bridging portion having a substantially constant inclination across the folding line, while at least one other conductive bridging portion may be implemented in a zig-zag or meander-like or triangular or sawtooth or sinusoidal shape. Herein, the zig-zag or meander-like or triangular or sawtooth shape of the folding line is a shape of a curve that resembles a piecewise linear function.

In some illustrative embodiments of the embodiments described in the preceding paragraph, the antenna inlay may further comprise a bridging substrate almost completely covering the inlay substrate for completely overlaying the antenna, wherein at least one bridge material portion is defined in the bridging substrate by lateral cutout gaps along the folding line. Herein, the cutout gaps are formed as zig-zag or meander-like or triangular or sawtooth or sinusoidal shaped cutouts matching a routing shape of the at least one conductive bridging portion and aligned therewith. Accordingly provided bridge material portions support to accommodate for mechanical stress when the antenna inlay is exposed to repeated mechanical bending.

In some illustrative embodiments of the first aspect, the antenna may further comprise a second antenna portion routed outside the folding line, e.g., at least in a substantially semicircular shape, and the first and second antenna portions may be located on opposite sides of the inlay substrate relative to the folding line. Furthermore, the at least one conductive bridging portion may be routed so as to electrically interconnect the first and second antenna portions. Accordingly, an antenna of greater shape extending over an area intersected by the folding line may be formed on the inlay substrate such that a size of the antenna is not constrained by the position and orientation of the folding line.

In some illustrative examples herein, the first antenna portion may be routed in a substantially circular shape forming a first coil winding portion with a first number of windings greater than or equal to one and the second antenna portion may be routed in a substantially circular shape forming a second coil winding portion with a second number of windings greater than or equal to one. Herein, the first and second coil winding portions are connected by the at least one conductive bridging portion in a series connection. Accordingly, the antenna may be formed from two coil winding portions which each adjust an inductance of the antenna.

In some special illustrative examples herein, the first and second coil winding portions may be formed with equal winding orientation in an open condition of the antenna inlay and with opposite winding orientation in a closed condition of the antenna inlay. Alternatively, the first and second coil winding portions may be formed with equal winding orientation in a closed condition of the antenna inlay and with opposite winding orientation in an open condition of the antenna inlay. Accordingly, the first and second coil winding portions may realize a first inductance adapted to provide the document with a first resonance frequency in a closed condition of the inlay substrate in which inlay substrate is folded along the folding line. The first and second coil winding portions may realize a second inductance adapted to provide the document with a second resonance frequency different from the first resonance frequency in an open condition of the inlay substrate in which the inlay substrate is unfolded to provide a substantially planar substrate configuration. These different resonance frequencies associated with the open and closed conditions of the inlay substrate allow for selectively communicating with the antenna in one condition, while blocking a communication with the antenna in the other condition when using a communication device adapted for communicating with the antenna at one of the first and second resonance frequencies. That is, upon matching the second resonance frequency with a resonance frequency of a communication device, a contactless communication with the antenna of the antenna inlay may be enabled in the open condition, while being blocked in the closed condition due to a mismatch between the first resonance frequency and the second resonance frequency. For example, the first resonance frequency may be detuned compared to an external ISO 14443 reader when being used as a communication device. In some illustrative examples herein, the first and second coil winding portions may be formed of planar coil winding portions corresponding to portions of planar air core coils. Accordingly, the first and second coil winding portions connected with one or more foldable bridging conductive tracks, provide an antenna for integration into a foldable document.

In some special illustrative examples herein, the first and second coil winding portions may have equal size and shape. Accordingly, an exact tuning of the resonance frequencies may be easily achieved.

In some other illustrative examples, the first and second antenna portions may be connected by the at least one conductive bridging portion so as to form an antenna coil winding with a number of windings greater than or equal to one. Accordingly, an antenna having a relatively large winding area may be provided without being constraint by position and orientation of the folding line. For example, the first and second antenna portions may be each routed in a substantially semicircular shape.

In some illustrative embodiments of the first aspect, the antenna inlay may further comprise an RF chip module electrically coupled with the antenna. Accordingly, the antenna inlay may advantageously provide a wireless communication function as an integral module. In some illustrative examples herein, the RF chip module may comprise an integrated circuit chip with contact terminals, the contact terminals being connected to the antenna.

In some illustrative embodiments of the first aspect, the antenna may be formed of a conductive material, e.g., aluminum and/or copper and/or silver and/or a metal alloy material and/or a conductive foil laminated with an insulated layer and/or a wire and/or a conductive ink. Accordingly, the conductive bridging portion may be simply provided without adding cost to the fabrication costs of the inlay substrate and without adding complexity to the fabrication of the antenna inlay. For example, the antenna may be formed by at least one of an etched metallic foil disposed over the inlay substrate or a metallic ink printed onto the inlay substrate or a wire embedded into the material of the inlay substrate. Accordingly, the antenna may be easily formed in an accurate manner. For example, the antenna may have a thickness of at most 100 μm such that the antenna may be fabricated at low cost without creating an uneven surface of the inlay substrate due to an extensive stepping in the surface of the inlay substrate.

In some illustrative embodiments of the first aspect, the antenna inlay may further comprise at least one bridge material portion such that each of the at least one conductive bridging portion is at least partially covered or at least partially embedded into the bridge material portion. The bridge material portion may protect its associated conductive bridging portion so as to further improve the lifetime of the antenna inlay when subjected to repeated folding. In some illustrative examples herein, each of the at least one bridge material portion may be formed and arranged so as to only cover at least partially a respective one of the at least one conductive bridging portion while leaving at least the first antenna portion substantially uncovered. This configuration may be advantageous in applications of a document with the antenna inlay being included into the document. In such document, a document layer is fixed to the inlay substrate in a manner so as to cover the antenna. The at least one bridge material portion may allow a mechanical decoupling of one or more conductive bridging portions from the document layer in that a relative mechanical movement of the one or more conductive bridging portions to the inlay substrate and the document layer when folding the inlay substrate. For example, the at least one bridge material portion may be fixed to the document page wherein relative movement of the respective conductive bridging portion is allowed. Additionally or alternatively, the bridge material portion may be formed of a material having a greater flexibility and/or elasticity than the inlay substrate. Accordingly, the antenna inlay may be advantageously provided as a monolayer inlay.

In some illustrative embodiments of the first aspect, the antenna inlay may further comprise a bridging substrate almost completely covering the inlay substrate for completely overlaying the antenna, wherein at least one bridge material portion is defined in the bridging substrate by lateral cutout gaps formed as strip shaped or zig-zag or meander-like or triangular or sawtooth or sinusoidal shaped, wherein the cutouts gaps are aligned with the folding line in a manner such that only the inlay substrate is partially exposed along the folding line. Accordingly, a multilayer configuration of the antenna inlay with embedded antenna may be provided where the at least one bridge material portion is integrated into a layer of the multilayer configuration.

In some illustrative embodiments of the first aspect, the inclination angle at the folding line deviates by at least 1° or 5° from 90°. Accordingly, an advantageous component of the conductive bridging portion extending parallel to the folding line and thus having an increasing component parallel to a maximum bending stress line is provided, thereby reducing tension in the conductive bridging portion across the folding line and prolonging fatigue to a break period. In a preferred example herein, the at least one conductive bridging portion may be inclined so as to substantially be as much parallel to the folding line as possible, e.g., deviating from the folding line by at most 45° or at most 30° or at most 25°, e.g., by about 16°.

In some illustrative embodiments of the first aspect, the first antenna portion may be routed so as to form an antenna coil, e.g. in a substantially circular shape, providing an antenna coil with at least one winding and the antenna inlay further comprises a chip module or two contact pads for electrical connection with the chip module, wherein the antenna is electrically coupled with the chip module or the two contact pads via the at least one conductive bridging portion. Herein and below, substantially circular shape represents a circular shape and a shape obtained by continuously deforming a circle. Accordingly, an antenna inlay with an antenna on one side of the inlay substrate relative to the folding line and a chip module or contact pads on another side of inlay substrate relative to the folding line may be provided. In an illustrative example, a rectangular planar antenna coil with rounded corners is considered as being of a substantially circular shape.

In some illustrative embodiments of the first aspect, track lines of the conductive bridging portion may have a first density of track lines and track lines of the first antenna portion may have a second density of track lines, the first density of track lines being greater than the second density of track lines. Accordingly, the track lines of the conductive bridging portion allow to efficiently absorb a bending force to have a longer fatigue period.

In some illustrative embodiments of the first aspect, track lines of the conductive bridging portion may have a first pitch of track lines and track lines of the first antenna portion may have a second pitch of track lines, the first pitch of track lines being smaller than the second pitch of track lines. In some examples herein, the first pitch may be at most 400 microns and the second pitch may be at least 450 microns or the first pitch may be at most 350 microns and the second pitch may be at least 400 microns or the first pitch may be at most 300 microns and the second pitch may be at least 350 microns or the first pitch may be at most 250 microns and the second pitch may be at least 300 microns. Accordingly, the track lines of the conductive bridging portion allow to efficiently absorb a bending force to have a longer fatigue period.

In a second aspect of the present disclosure, a document is provided. In the embodiments herein, the document has the antenna inlay of the first aspect and a foldable document base with a hinge region having a folding line, wherein the antenna inlay is mechanically coupled with the document base such that the folding lines of the document base and the antenna inlay substantially coincide. Accordingly, a foldable document with integrated antenna inlay may be provided. The hinge region allows the document to be closed by arranging a top covering page and a bottom covering page in a stacked arrangement, while the document may be open when unfolding the stacked arrangement of the top and bottom covering pages. For example, each of the top and bottom covering pages may be connected to the hinge region via a respective fold, the folds being arranged substantially in parallel and the folds being substantially in parallel with the folding line.

In the second aspect, the antenna of the antenna inlay of the document may function as a shielding in a closed condition of the document as an inductance of the antenna in a closed condition substantially deviates from an inductance of the antenna in an open condition of the document due to a shift in the resonance frequency between open and closed conditions. It may thus be ensured in the closed condition of the document that unintended reading of the document is inhibited. By contrast, when opening the document such that the antenna is unfolded, i.e., antenna portions are not in a stacked arrangement as in the closed condition, and exposed to an authorized reader, the unfolded antenna functions as a communication antenna, allowing the authorized reader to read the document. In the open condition of the document, the document may be unfolded such that an angle formed by a top covering page and a bottom covering page of the document may be substantially greater than 10°, preferably greater 45° or greater than 90° or greater than 120°, more preferably greater than 150° degrees and smaller than 250° or smaller than 220°. In other words, the unfolded antenna functions in the open condition of the document as a unique antenna, while the folded antenna provides a shielding function in the closed condition of the document. Therefore, the unfolded antenna may be exposed to an authorized reader in the open condition for allowing the authorized reader to communicate with an RF chip module via the unfolded antenna, while the document in the closed condition does not allow unintended communication with an RF chip module in a reliable and easy manner.

In some illustrative embodiments, the conductive bridging portion may completely extend across the hinge region. Accordingly, mechanical strain being imposed across the hinge region may be accommodated by the at least one conductive bridging portion.

In some other illustrative embodiments, the document may be a booklet having a booklet cover formed by the first and second pages and one or more additional pages connected to the hinge region, the one or more pages being enclosed by the booklet cover. Accordingly, a booklet with a contactless communication feature may be provided.

### BRIEF DESCRIPTION OF THE DRAWINGS

The present invention will be explained in greater detail with regard to the accompanying drawings in which:

FIG. 1 schematically illustrates, in a schematic top view, an antenna inlay in accordance with some illustrative embodiments of the present disclosure in an unfolded condition;

FIG. 2 schematically illustrates, in a schematic top view, a document including the antenna inlay of FIG. 1 in an unfolded condition;

FIG. 3 schematically illustrates, in a schematic top view, the document of FIG. 2 in a folded condition;

FIG. 4 schematically illustrates, in a schematic side-sectional view, an arrangement for reading the document of FIGS. 2 and 3 in which the document is in the folded condition;

FIG. 5 schematically illustrates, in a schematic side-sectional view, the arrangement of FIG. 4 where the document is in a condition in which it is not completely folded;

FIG. 6 schematically illustrates, in a schematic and exploded perspective side-sectional view, a document in accordance with some illustrative embodiments where an antenna inlay has a multilayer configuration;

FIG. 7 schematically illustrates, in a schematic and exploded perspective side-sectional view, a document in accordance with some other illustrative embodiments where an antenna inlay has a monolayer configuration;

FIGS. 8a to 8e schematically illustrate, in schematic top views, various different antenna layouts of an inlay antenna;

FIG. 9 schematically illustrates, in a schematic top view, an antenna layout in accordance with some special illustrate examples of the present disclosure;

FIGS. 10 and 12 schematically illustrates, in a schematic top view, different antenna layouts in accordance with various special illustrate examples of the present disclosure; and

FIGS. 11 and 13 schematically illustrates, in a schematic top view, bridging material portions according to the antenna layouts of the various special illustrative examples of FIGS. 10 and 12.

### DETAILED DESCRIPTION

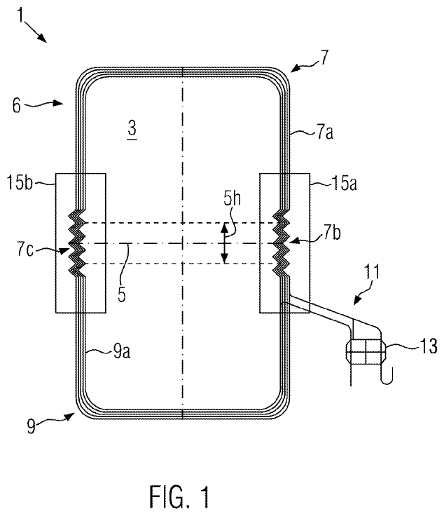

Referring to FIG. 1, an antenna inlay 1 in accordance with some illustrative embodiments of the present disclosure for a document (not illustrated) is schematically shown in a top view. The antenna inlay 1 comprises an inlay substrate 3 which is foldable along a folding line 5. In some illustrative examples herein, the inlay substrate 3 may be flexible substrate as employed in a flexible circuit board which may be repeatedly folded, or it may be made of a material plate with appropriate mechanical characteristics for allowing repeatedly folding and unfolding. For example, the inlay substrate 3 may comprise a sheet of material such as at least one of a piece of paper, a piece of cardboard, a piece of paperboard, a piece of millboard, a piece of pasteboard, a piece of corrugated fiberboard, a board of polycarbonate material and a paper-based material and a synthetic fiber paper and/or the like. In the context of the present disclosure, synthetic fiber paper may be understood as representing a non-cellulosic sheet material resembling paper and used in a similar fashion, typically made from thermoplastic materials such as polyolefins, nylon, polystyrene, etc., by direct film or foil extrusion or by bonding filaments thereof. Additionally or alternatively, synthetic fiber paper may be understood as representing a category of paper that is made without any wood fibers and is especially formulated to be receptive to commercial printing inks. In any way, synthetic fiber paper differs from a plastic film with respect to printing characteristics and it differs from traditional paper due to the lack of wood fibers. In other words, synthetic fiber paper is considered as being a paper-like film that lies somewhere between traditional plastic films and high-value paper. As opposed to traditional paper, synthetic fiber papers use a plastic resin backbone rather than the pulped wood fibers used in traditional paper. However, synthetic fiber papers and traditional papers both use mineral fillers and optical brighteners to gain opacity, brightness and smoothness. Therefore, printability characteristics for synthetic fiber papers and traditional papers formed of a wood pulp are comparably developed by the use of calendering rolls and imparting surface printability enhancements.

In accordance with some illustrative examples, the inlay substrate 3 may be provided as a continuous sheet of material and may be cut to desired dimensions during fabrication of the antenna inlay 1 or in further processing during the preparation of a document (not illustrated) including the antenna inlay 1. For example, the inlay substrate 3 may substantially have a homogeneous thickness and/or a homogeneous stiffness.

As shown in FIG. 1, the inlay antenna 1 further comprises an antenna 6 formed on or embedded into the inlay substrate 3. The antenna 6 comprises a first antenna portion 7 having at least one first antenna track portion 7a routed outside the folding line at least in a substantially semicircular shape. The antenna 6 further comprises a conductive bridging portion 7b routed to extend across the folding line.

In accordance with illustrative embodiments herein, the first antenna track portion 7a is routed outside a hinge region 5h of the inlay substrate 3, the hinge region 5h representing a region of the inlay substrate 3 being bend into a curved shape when folding the inlay substrate 3 along the folding line 5. In this sense, the hinge region 5 represents a region of the inlay substrate 3 in the top view of FIG. 1, where the inlay substrate 3 is not planar when subjected to a folding operation. Accordingly, the first antenna portion 7, and accordingly each antenna track portion 7a, represents portions of the antenna 6 routed outside the hinge region 5h, wherein the first antenna portion 7, and accordingly each first antenna track portion 7a, is arranged on one side of the folding line 5. In other words, the first antenna portion, and accordingly each first antenna track portion 7a, is formed on or embedded into a region of the inlay substrate 3 outside the hinge region 5h without being intersected by the folding line 5.

Referring to the illustrative but non-limiting embodiment shown in FIG. 1, each first antenna track portion 7a of the first antenna portion 7 represents a continuous line portion of the first antenna portion 7 such as a winding line section of the antenna 6 routed outside the hinge region 5h. In this regard, the first antenna portion 7 may comprise one or more discrete first antenna track portions 7a routed parallel to each other as indicated in the illustration in FIG. 1. This does not impose any limitation and the first antenna portion 7 may be formed by only one continuous antenna line portion although this is not illustrated in FIG. 1.

With ongoing reference to FIG. 1, the conductive bridging portion 7b is electrically connected with the first antenna portion 7 such that each first antenna track portion 7a is electrically coupled with a respective bridging track line of the conductive bridging portion 7b.

In accordance with illustrative embodiments herein, the conductive bridging portion 7b is routed within the hinge region 5h so as to cross the folding line 5 at an inclination angle unequal to 90°. For example, the inclination angle may deviate from 90° by at least 1° or at least 5°. The inventors understood that an inclination angle deviating from 90° results in a component of the conductive bridging portion 7b extending parallel to the folding line 5. With increasing deviation, the conductive bridging portion 7b thus has an increasing component parallel to a maximum bending stress line caused by bending of the inlay substrate 3 across the folding line 5. In this way, tension is reduced in each bridging track line of the conductive bridging portion 7b across the folding line 5. In special illustrative examples herein, each bridging track line of the conductive bridging portion 7b is inclined so as deviating from the folding line by at most 45° or at most 30° or at most 25° for assuming a routing substantially as much parallel to the folding line 5 as possible and necessary. In a special illustrative example herein, each bridging track line of the conductive bridging portion 7b is inclined so as deviating from the folding line by about 16° for assuming a routing substantially as much parallel to the folding line 5 as possible and necessary.

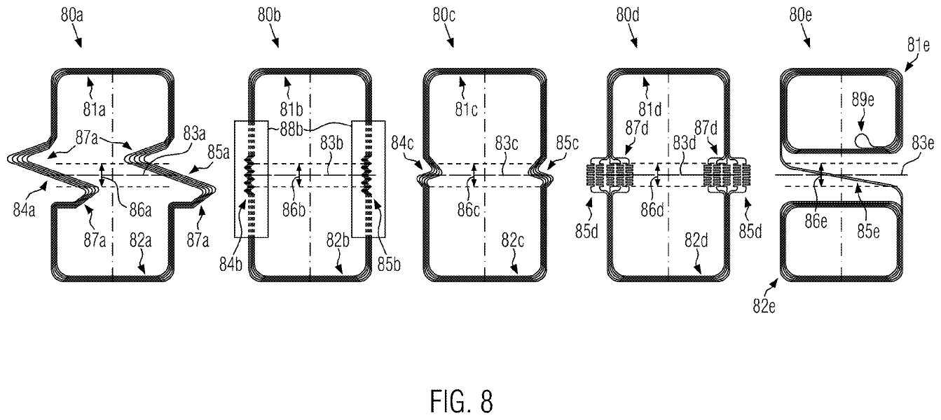

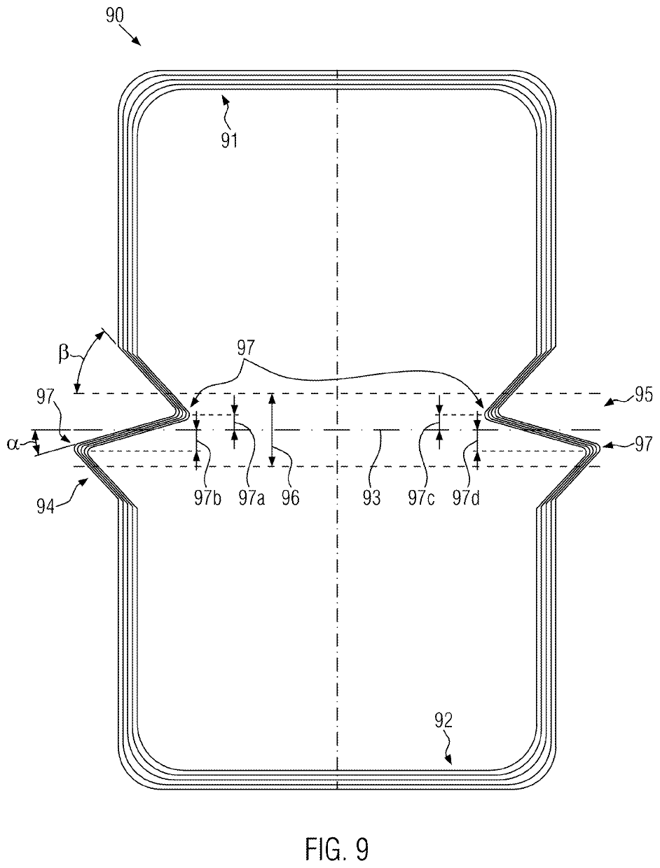

As illustrated in FIG. 1 and in accordance with some illustrative embodiments herein, the conductive bridging portion 7b may be routed in a zig-zag or meander-like or triangular or sawtooth shape relative to the folding line 5 as long as each bridging track line of the conductive bridging portion 7b directly crosses the folding line 5 under an inclination angle different from 90°. The specific shape of the conductive bridging portion 7b and its bridging track lines shown in FIG. 1 is only illustrative and not limiting. Further examples of alternative shapes of the conductive bridging portion 7b will be discussed below with regard to FIGS. 8a to 8e and FIG. 9. As illustrated in FIG. 1, the zig-zag or meander-like or triangular or sawtooth shape of the folding line is a shape of a curve that resembles a piecewise linear function.

In some illustrative embodiments and as shown in FIG. 1, the antenna 6 may further comprise a second antenna portion 9 routed outside the folding line 5 in a substantially semicircular shape. Similarly to the first antenna portion 7, the second antenna portion 9 comprises one or more second antenna track portions 9a which may be understood as representing part of the antenna 6 routed outside the hinge region 5h on a side of the folding line 5 opposite the first antenna portion 7. In other words, the second antenna track portions 9a are formed on or embedded into a region of the inlay substrate 3 outside the hinge region 5h without intersecting the folding line 5.

In the illustration of FIG. 1, the first and second antenna portions 7 and 9 are each routed in a substantially semicircular shape, being interconnected by the conductive bridging portions 7b on one side and by conductive bridging portions 7c on an opposite side along the folding line 5. Accordingly, the antenna 6 forms an antenna coil winding structure with a number of windings greater than or equal to one across the inlay substrate, even across the folding line 5. In this way, an antenna having a relatively large winding area may be provided without being constrained by a position and orientation of the folding line 5.

In accordance with illustrative embodiments herein and the illustration in FIG. 1, each of the first antenna track portions 7a and each of the second antenna track portions 9a is electrically coupled with a respective bridging track line of the conductive bridging portion 7b and with a respective bridging track line of the conductive bridging portion 7c such that the antenna 6 forms the antenna coil winding structure with at least one winding across the inlay substrate. In illustrative examples herein, where the antenna 6 is formed by a plurality of windings, i.e., the number of windings is greater than one, a density of track lines in each of the antenna track portions 7a, 9a and the bridging portions 7b, 7c may be equal or substantially equal or may be different. For example, the densities of track lines in the portions 7a, 7b, 7c, 9a may be different such that each portion of the portions 7a, 7b, 7c, 9a may have an individual density different from densities in the other portions of the portions 7a, 7b, 7c, 9a, wherein the densities of track lines in the conductive bridging portions 7b, 7c is greater than the densities of track lines in the antenna track portions 7a, 9a. According to some special illustrative example herein, the conductive bridging portions 7b, 7c may substantially have a first density of track lines and the antenna track portions 7a, 9a may substantially have a second density, wherein the first density is greater than the second density. A density of track lines may be defined as a number of track lines extending in a reference area portion, where a reference area portion is an area portion of a specific areal size (e.g., without limitation any area with a size of about 1 mm2) in which neighboring track lines substantially extend linearly in parallel.

In some special illustrative embodiments as discussed above, a density may be equivalently quantized by a pitch of track lines or in other words, a pitch of track lines in a portion of the antenna 6 may be considered as being equivalent to a density of the track lines. Herein, a higher density of track lines is equivalent to a lower pitch of track lines. For example, the pitches of track lines in the portions 7a, 7b, 7c, 9a may be different such that each portion of the portions 7a, 7b, 7c, 9a may have track lines with an individual pitch of track lines different from pitches of track lines in the other portions of the portions 7a, 7b, 7c, 9a, wherein the pitches of track lines in the conductive bridging portions 7b, 7c is smaller than the pitches of track lines in the antenna track portions 7a, 9a. As a special illustrative example, the track lines of the conductive bridging portions 7b, 7c may substantially have a first pitch of track lines and the antenna track portions 7a, 9a may substantially have a second pitch of track lines, wherein the first pitch is smaller than the second pitch. For example, the first pitch may be at most 400 microns and the second pitch may be at least 450 microns or the first pitch may be at most 350 microns and the second pitch may be at least 400 microns or the first pitch may be at most 300 microns and the second pitch may be at least 350 microns or the first pitch may be at most 250 microns and the second pitch may be at least 300 microns.

Accordingly, the track lines of the conductive bridging portions 7b and 7c allow to absorb a bending force to have a longer fatigue period.

Similarly to the conductive bridging portion 7b, the conductive bridging portion 7c is routed within the hinge region 5h so as to cross the folding line 5 at an inclination angle unequal to 90° and comprises at least one bridging track line. In some illustrative examples herein, the inclination angle may deviate from 90° by at least 1° or at least 5°. In special illustrative examples herein, each bridging track line of the conductive bridging portion 7c is inclined so as to deviate from the folding line by at most 45° or at most 30° or at most 25°, assuming a routing substantially as much parallel to the folding line 5 as possible and necessary. In a special illustrative example herein, each bridging track line of the conductive bridging portion 7c is inclined so as deviating from the folding line by about 16° for assuming a routing substantially as much parallel to the folding line 5 as possible and necessary.

As illustrated in FIG. 1, the conductive bridging portions 7c, and accordingly each bridging track line, may be routed in a zig-zag or meander-like or sinusoidal shape relative to the folding line 5 as long as a part of each bridging track line of the conductive bridging portion 7c directly crosses the folding line 5 under an inclination angle different from 90°. The specific shape of each bridging track line of the conductive bridging portion 7b shown in FIG. 1 is only illustrative and not limiting. Further examples of alternative shapes for the conductive bridging portions 7c will be discussed below with regard to FIGS. 8a to 8e and FIG. 9. As illustrated in FIG. 1, the zig-zag or meander-like or triangular or sawtooth shape of the folding line is a shape of a curve that resembles a piecewise linear function.

In some illustrative embodiments herein, the antenna inlay 1 may further comprise a chip module 13 electrically coupled with the antenna 6 at end terminals 11 of the antenna 6. The chip module 13 may be an RF chip module or a contact pad arrangement (not illustrated) may be provided instead of the chip module 13 for coupling the antenna 6 of the antenna inlay 1 with a chip module (not illustrated) of a document (not illustrated) into which the antenna inlay 1 is to be integrated.

In some illustrative embodiments herein, the antenna 6 may be formed of a conductive material, e.g., aluminum and/or copper and/or silver and/or a metal alloy material and/or a conductive foil laminated with an insulated layer and/or a wire and/or a conductive ink. Accordingly, the conductive bridging portions 7b and 7c may be simply provided without adding cost to the fabrication costs of the inlay substrate 3 and without adding complexity to the fabrication of the antenna inlay 1. For example, the antenna 6 may be formed by at least one of an etched metallic foil disposed over the inlay substrate 3 or a metallic ink printed onto the inlay substrate 3 or a wire embedded into the material of the antenna inlay 3. For example, the antenna 6 may have a thickness of at most 100 μm such that the antenna 6 may be fabricated at low cost without creating an uneven surface of the inlay substrate 3 due to an extensive stepping in the surface of the inlay substrate 3.

Referring to FIG. 1, the antenna inlay 1 further comprises bridge material portions 15a and 15b covering the conductive bridging portions 7b, 7c or embedding the conductive bridging portions 7b, 7c into the bridge material portions 15a, 15b. The bridge material portions 15a, 15b protect the conductive bridging portions 7a, 7b when subjected to repeated folding. In some illustrative examples, the bridge material portions 15a, 15b are formed and arranged so as only to cover the conductive bridging portions 7b and 7c while leaving the first and second antenna portions 7 and 9 outside the hinge region 5h substantially uncovered.

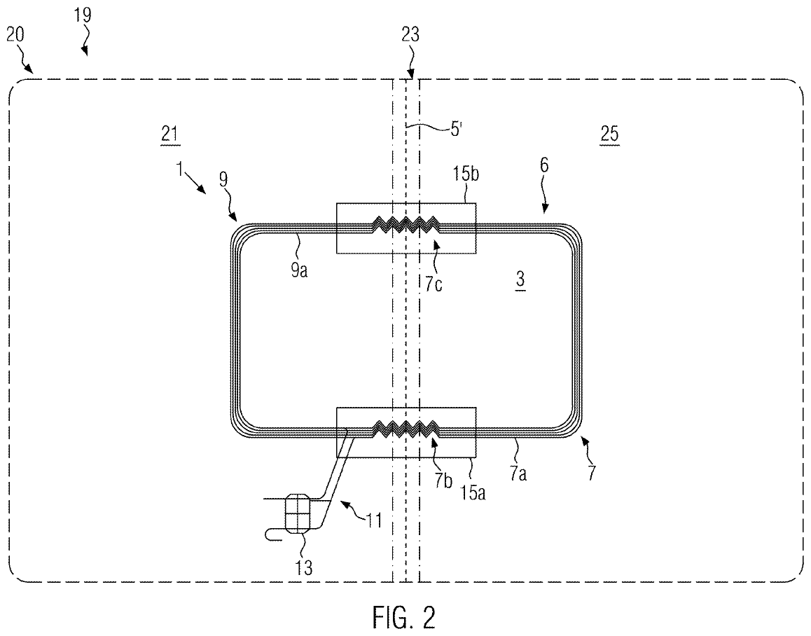

With reference to FIG. 2, a document 19 is shown in a schematic top view. The document 19 comprises a document base 20 and the antenna inlay 1 described above with regard to FIG. 1, wherein the antenna inlay 1 is attached to the document base 20. The document base 20 comprises two covering portions 21 and 25 mechanically coupled by a hinge region 23. The hinge region 23 is a region of the document base 20 which is deformed upon folding of the document 19 along a folding line 5′. The folding line 5′ basically corresponds to the folding line 5 of the inlay substrate 1 as described above in the context of FIG. 1. When subjected to folding, the hinge region 23 becomes deformed and the covering portions 21 and 25 substantially remain planar and unfolded. The entire disclosure as described above with regard to FIG. 1 is incorporated in its entirety.

In this respect, an open condition of the document 19 is considered as indicating a condition or state of the document 19 in which the document 19 is substantially unfolded and the covering portions 21 and 25 together with the hinge region 23 are substantially arranged in a lateral arrangement as seen in the top shown in FIG. 2. In particular, the antenna inlay 1 is mechanically coupled to the document base 19 such that the folding lines of the document base 20 and the antenna inlay 1 substantially coincide in the folding line 5′. The conductive bridging portions 7b and 7c of the antenna 6 completely extend across the hinge region 23.

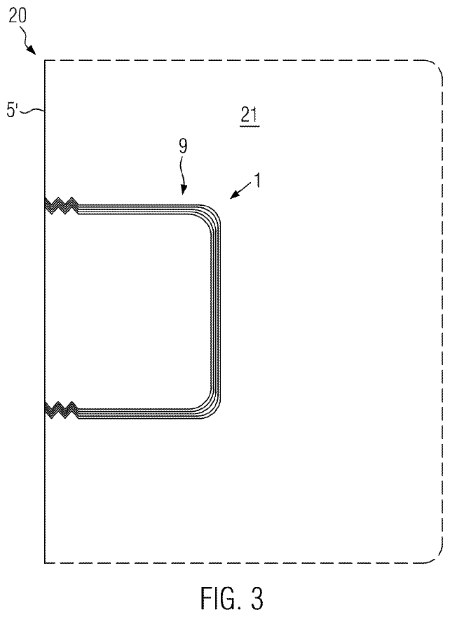

Referring to FIG. 3, document 19 is shown in a closed condition, representing a condition or state of the document 19 in which the covering portions 21 and 25 are arranged in a stacked configuration, one of the covering portions 21 and 25 being arranged over another of the covering portions 21 and 25. For example, the illustration in FIG. 3 shows the document 19 in the closed condition in which the document 19 is folded and the covering portion 21 is arranged over the covering portion 25. This does not impose any limitation and the document 19 may be folded such that the covering portion 25 may be arranged on the covering portion 21. Accordingly, each covering portion may be considered as representing a page of the document 19.

In some illustrative embodiments herein, the document base 20 may be a cover stock of a booklet type document. For example, the document base 20 may be made of at least one of a piece of paper, a piece of cardboard, a piece of paperboard, a piece of millboard, a piece of pasteboard, a piece of corrugated fiberboard, a board of polycarbonate material and a paper-based material and a synthetic fiber paper and/or the like. As indicated above, synthetic fiber paper is a non-cellulosic sheet material resembling paper and used in a similar fashion, typically made from thermoplastic materials such as polyolefins, nylon, polystyrene, etc., by direct film or foil extrusion or by bonding filaments thereof. Additionally or alternatively, synthetic fiber paper may represent a category of paper made without any wood fibers and is especially formulated to be receptive to commercial printing inks. In any way, synthetic fiber paper differs from a plastic film with respect to printing characteristics and it differs from traditional paper due to the lack of wood fibers. In other words, synthetic fiber paper is considered as being a paper-like film that lies somewhere between traditional plastic films and high-value paper. As opposed to traditional paper, synthetic fiber papers use a plastic resin backbone rather than the pulped wood fibers used in traditional paper. However, synthetic fiber papers and traditional papers both use mineral fillers and optical brighteners to gain opacity, brightness and smoothness. Therefore, printability characteristics for synthetic fiber papers and traditional papers formed of a wood pulp are comparably developed by the use of calendering rolls and imparting surface printability enhancements.

In accordance with some illustrative embodiments herein, the document 19 may be a booklet having a booklet cover formed by the covering portions 21 and 25. The booklet may optionally further include one or more additional pages connected to the hinge region 23, the one or more pages being enclosed by the booklet cover 21, 25. Accordingly, an epassport may be provided in a special illustrative and non-limiting example.

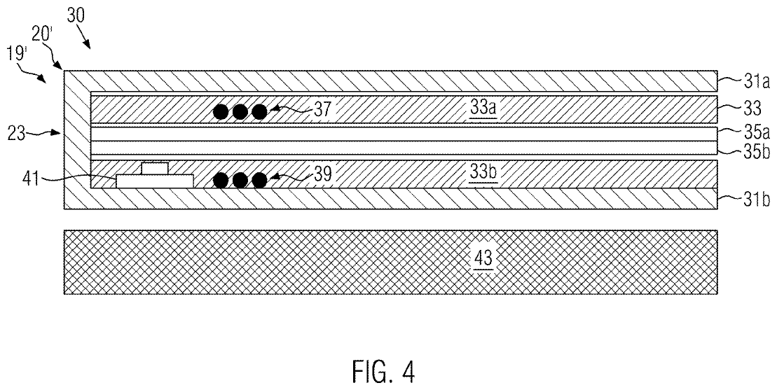

Referring to FIG. 4, a reading arrangement 30 is schematically illustrated in a cross-sectional view. The reading arrangement 30 comprises a document 19′ together with a reading device 43, wherein the document 19′ is in the closed condition. The document 19′ may correspond or be similar to the document 19 as described above with regard to FIGS. 2 and 3. That is, the document 19′ has a document base 20′ formed by covering portions 31a and 31b mechanically connected by a hinge region 23′. The covering portions 31a and 31b may represent top cover and bottom cover of the document 19′ and may be formed similarly to or in accordance with the covering portions 21 and 25 as described above in the context of FIGS. 2 and 3, the disclosure of which is incorporated by reference in its entirety.

With ongoing reference to FIG. 4, the document 19′ has an antenna inlay with an antenna formed therein, the antenna inlay comprising an inlay substrate 33 into which the antenna is embedded as indicated by antenna windings 37 in a top portion 33a of the folded inlay substrate 33 and antenna windings 39 in a bottom portion 33b of the folded inlay substrate 33. This does not impose any limitation and the antenna may be formed on the inlay substrate 33.

In accordance with illustrative embodiments, a chip module 41 is provided in electrical connection with the antenna such that the reading device 43 may communicate with the chip module 41 in a contactless manner for reading electronic information of the document 19′. In particular, the antenna windings 37 and 39 of the document 19′ have a first inductance adapted to provide the document 19′ with a first resonance frequency in the depicted closed condition of the document 19′ in which the document 19′ is folded such that the top portion 33a is placed on the bottom portion 33b. By contrast, the antenna has a second inductance adapted to provide the document 19′ with a second resonance frequency different from the first resonance frequency in the open condition (not illustrated in FIG. 4) of the document 19′ in which the inlay substrate 33 is unfolded and the top portion 33a is arranged laterally aside the bottom portion 33b, the hinge region 23′ being unfolded. Accordingly, upon matching a resonance frequency of the reading device 43 with the second resonance frequency, while detuning the first resonance frequency with regard to the resonance frequency of the reading device 43, the reading device 43 representing an external reader is not able to communicate with the chip module 41 of the document 19′ in the closed condition. For example, the second resonance frequency may be in a range from about 10 MHz to about 15 MHz, preferably in a range from about 11 MHz to about 14 MHZ, such as about 13.5 MHz. The first resonance frequency may deviate from the second resonance frequency by at least 5% or at least 10% or at least 20% of the second resonance frequency. For example, the first resonance frequency may be greater than 14 MHz or greater than 15 MHz or greater than 19 MHZ, e.g., in a range from about 19 MHz to about 21 MHz. Accordingly, reading of the document 19′ in the reading arrangement shown in FIG. 4 is inhibited as a resonance frequency of the antenna in the depicted closed condition is shifted relative to the resonance frequency of the reading device 43.

In a testing probe subjected to ISO testing with a reading distance between reading device 43 and document 19′ of about 6 cm, a first resonance frequency of about 23 MHz was measured while a first resonance frequency of about 14 MHz was obtained in the open condition upon using a Changi pick coil with power of 10 dBm.

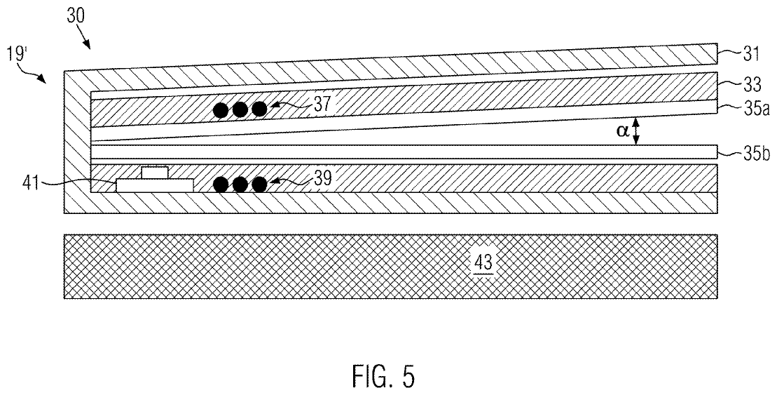

Referring to FIG. 5, a testing of the document 19′ in a partially closed condition was performed, wherein an angle α>0 was adjusted such that the top portion 33a and the bottom portion 33b had a maximum gap spacing of about 10 mm, preferably a gap spacing in a range from 8 mm to 10 mm. In this case, the testing resulted in a first resonance frequency of about 20 MHz such that reading of the document 19′ is sufficiently inhibited even in the partially closed condition. It is noted that a detuning of the resonance frequency of the document 19′ with respect to the resonance frequency of the reading device 43 is becoming smaller with increasing gap spacing between the top portion 33a and the bottom portion 33b.

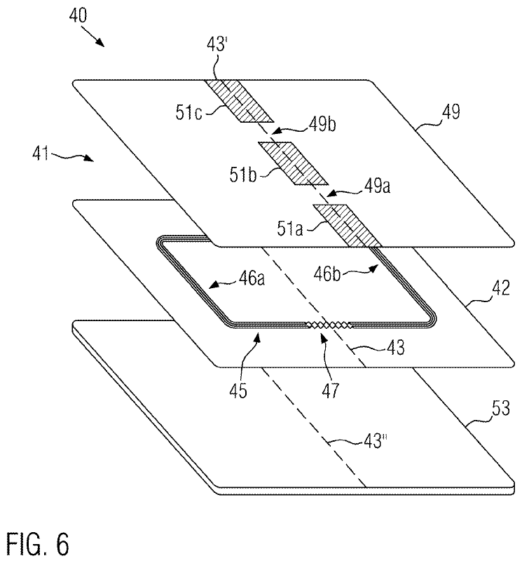

With reference to FIG. 6, a document 40 with an antenna inlay 41 of a multilayer configuration is provided. The antenna inlay 41 comprises an inlay substrate 42 on which an antenna 45 having semicircular antenna portions 46a and 46b being electrically coupled by conductive bridging portions 47 are formed. The antenna portions 46a and 46b each comprise at least one antenna track portion. FIG. 6 only shows one conductive bridging portion while the other conductive bridging portion opposite the visible conductive bridging portion is not visible in the exploded view of FIG. 6. The conductive bridging portions 47 extend across a folding line 43 of the inlay substrate 42 and each comprise at least one bridging track line. The inlay substrate 42 with the antenna 45 may be similar to or substantially correspond to the inlay substrate and antenna as described above with regard to any of FIGS. 1 to 5, the disclosure of which is incorporated in its entirety by reference.

With ongoing reference to FIG. 6, the antenna inlay 41 further comprises a bridging substrate 49 almost completely covering the inlay substrate 42. The antenna 45 is completely covered by the bridging substrate 49 and the bridging substrate 49 completely overlays the antenna 45 on the inlay substrate 42.

In accordance with illustrative embodiments and as illustrated in FIG. 6, the bridging substrate 49 is arranged on the inlay substrate 42 such that the folding line 43 is substantially aligned with a folding line 43′ of the bridging substrate 49. The bridging substrate 49 has lateral cutout gaps 51a, 51b, 561c formed therein, the cutout gaps 51a to 51c exposing surface regions of the inlay substrate below the bridging substrate 49. In particular, the cutout gaps 51a to 51c are formed so as to substantially not have any overlap with the antenna 45. For example, neither of the antenna portions 46a and 46b and the conductive bridging portions 47 are at least partially exposed by the bridging substrate 49. However, this does not impose any limitation on the present disclosure and at least one of the cutout gaps 51a to 51c may partially expose at least one of the antenna portions 46a and 46b and the conductive bridging portions 47.

In accordance with some illustrative embodiments, the bridging substrate 49 may be formed of a waterproof synthetic printing medium, such as a Teslin material. For example, the bridging substrate 49 may be made of the same material as the inlay substrate 42 and no gap material may be employed. In some special illustrative examples, the bridging substrate 49 is made of Teslin material and the Teslin material forms a bridge connected to both sides of a partial cut-out, front and rear side of the cut-out.

In some illustrative examples, the bridge layer substrate 49 may be attached directly to the inlay substrate 42 by a mounting and heat lamination process.

In accordance with illustrative embodiments herein, the cutout gaps 51a to 51c define conductive bridging portions 49a and 49b overlaying the conductive bridging portions 47. The cutout gaps 51a to 51c are formed as strip shaped cutouts aligned with the folding line such that only the inlay substrate is partially exposed along the folding line and remaining material of the bridging substrate 49 covering the inlay substrate 42 and separating adjacent ones of the cutout gaps 51a to 51c are left as covering the conductive bridging portions 47 at least at the folding line 43.

As shown in FIG. 6, the document 40 further comprises a document base 53 similar to a document base as described above with regard to FIGS. 2 to 5, the disclosure of which is incorporated by reference in its entirety. The inlay substrate 43 may be attached to the document base 53 such that the folding line 43 of the inlay substrate is in alignment with a folding line 43″ of the document base 53. In the document 40, the inlay substrate 42 is sandwiched between the document base 53 and the bridging substrate 49 being arranged on the antenna 45.

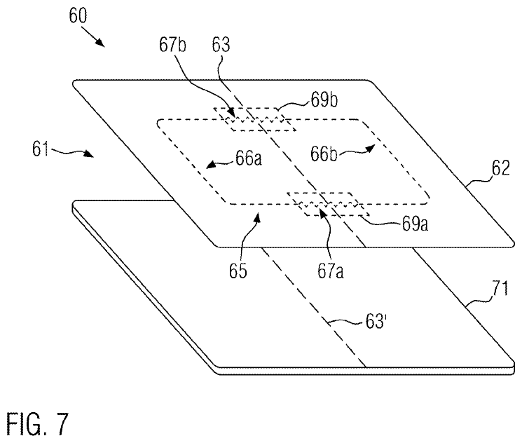

Referring to FIG. 7, a document 60 with an antenna inlay 61 of a monolayer configuration is provided. The antenna inlay 61 comprises an inlay substrate 62 on which an antenna 65 having semicircular antenna portions 66a and 66b being electrically coupled by conductive bridging portions 67a and 67b are formed, the conductive bridging portions 67a and 67b extending across a folding line 63 of the inlay substrate 62 and each comprising at least one bridging track line. The antenna portions 66a and 66b each comprise at least one antenna track portion. The inlay substrate 62 with the antenna 65 may be similar to or substantially correspond to the inlay substrate and antenna as described above with regard to any of FIGS. 1 to 5, the disclosure of which is incorporated in its entirety by reference.

In accordance with illustrative embodiments herein, the antenna inlay 61 further comprises bridge material portions 69a and 69b which are formed on the inlay substrate 62 such that each of the conductive bridging portions 67a and 67b is covered by a respective one of the bridge material portions 69a and 69b. For example, the bridge material portions 69a and 69b are formed and arranged on the inlay substrate 62 so as to only cover the conductive bridging portions 67a and 67b, while otherwise leaving the antenna 65 substantially uncovered.

With ongoing reference to FIG. 7, the antenna inlay 61 is attached to a document base 71 of the document 60 such that the antenna 65 is facing towards an upper surface of the document base 71. For example, the upper surface of the document base 71 may be covered with an adhesive and the antenna inlay 62 is adhered to the document base 71 with the antenna 65 being directed towards the document base 71 (indicated in the illustration in FIG. 7 due to the antenna 65 and the bridge material portions 69a and 69b being drawn in broken lines) and being brought into contact with the document base 71. It is noted that the conductive bridging portions 67a and 67b are protected from being brought into contact with the document base 71 due to the bridge material portions 69a and 69b covering the conductive bridging portions 67a and 67b.

Referring to FIGS. 8a to 8e, various designs for an antenna will be described in greater detail. The person skilled in the art will appreciate that any of the antennas as described above with regard to FIGS. 1 to 7 may be replaced by one of the antennas as described below with regard to FIG. 8. Accordingly, a specific design or layout of an antenna as shown in FIGS. 1 to 7 and described above is not limiting but rather illustrative and another layout or design as becomes apparent from the below, can be employed instead.

With reference to FIG. 8a, a design or layout of an antenna 80a is schematically illustrated in a top view. The antenna 80a comprises semicircular antenna portions 81a and 82a formed on an inlay substrate (not illustrated) at opposing sides of the substrate (not illustrated) relative to a folding line 83a. The antenna portions 81a and 82a each comprise at least one antenna track portion and are electrically coupled by conductive bridging portions 84a and 85a. The conductive bridging portions 84a and 85a extend across a hinge region 86a of the inlay substrate (not illustrated) which represents a portion of the inlay substrate (not illustrated) that becomes deformed when folding the inlay substrate (not illustrated) along the folding line 83a. The conductive bridging portions 84a and 85a are routed linearly at a constant inclination relative to the folding line 83a with an inclination angle different from 90° relative to the folding line 83a. For example, the inclination may deviate from the folding line 83a by at most 45° or at most 30° or at most 25°, e.g., by about 16°, such that the conductive bridging portions 84a and 85a are substantially as parallel as possible to the folding line 83a. Additionally or alternatively, the inclination angle relative to the folding line 83a may deviate from 90° by at least 1° or at least 5°.

In accordance with some illustrative embodiments, the conductive bridging portions 84a and 85a may each comprise plural conductive track lines so as to supplement the semicircular antenna portions 81a and 82a across the hinge region 86a. Accordingly, each antenna track portion is electrically coupled with a respective conductive track line of the conductive bridging portion 84a and a respective conductive track line of the conductive bridging portion 85a. In this way, the antenna 80a implements a winding coil with a winding number depending on the amount of track lines extending across the hinge region 86a. For example, two track lines extending across the hinge region 86a and connecting the conductive bridging portions 84a and 85a to form the antenna 80a implies a winding number of one, while four track lines extending across the hinge region 86a and connecting the conductive bridging portions 84a and 85a to form the antenna 80a implies a winding number of two. In general, a number of n track lines (n being an even integer greater zero) extending across the hinge region 86a and connecting the conductive bridging portions 84a and 85a to form the antenna 80a implies a winding number of n/2.

In accordance with some illustrative embodiments and as shown in FIG. 8a, the conductive bridging portions 84a and 85a may couple to the semicircular antenna portions 81a and 82a outside the hinge region 86a via curved routing portions 87a. In some special illustrative and non-limiting example herein, the curved routing portions 87a may be of a substantially semicircular or semi-sinusoidal shape. The curved routing portions 87a allow to elastically compensate mechanical strain acting along a direction perpendicular to the folding line 83a.

In accordance with illustrative embodiments herein and the illustration in FIG. 8a, each of the semicircular antenna portions 81a, 82a is electrically coupled with a respective bridging track line of the conductive bridging portions 84a, 85a such that the antenna 80a having an antenna coil winding structure with at least one winding across the inlay substrate is formed.

With reference to FIG. 8b, a design or layout of an antenna 80b is schematically illustrated in a top view. The antenna 80b comprises semicircular antenna portions 81b and 82b formed on an inlay substrate (not illustrated) at opposing sides of the inlay substrate (not illustrated) relative to a folding line 83b and each having at least one antenna track portion. The antenna portions 81b and 82b are electrically coupled by conductive bridging portions 84b and 85b extending across a hinge region 86b of the inlay substrate (not illustrated) which represents a portion of the inlay substrate (not illustrated) that becomes deformed when folding the inlay substrate (not illustrated) along the folding line 83b. The conductive bridging portions 84b and 85b are routed in a zig-zag or meander-like or triangular or sawtooth shaped manner across the hinge region 86b such that each conductive track line of the conductive bridging portions 84b and 85b extends across the folding line 83b with an inclination angle relative to the folding line 83b different from 90°. In particular, each conductive track line of the conductive bridging portions 84b and 85b may have an inclination angle at the folding line 83b which deviates from the folding line 83b by at most 45° or at most 30° or at most 15° or at most 10°. Accordingly, the conductive bridging portions 84b and 85b substantially become as parallel as possible to the folding line 83b. Additionally or alternatively, the inclination angle of each conductive track line of the conductive bridging portions 84b and 85b at the folding line 83b may deviate from 90° relative to the folding line 83b by at least 1° or at least 5°.

In accordance with some illustrative embodiments, the conductive bridging portions 84b and 85b each comprise at least one conductive track line supplementing the semicircular antenna portions 81b and 82b across the hinge region 86b to form one or more antenna winding on the inlay substrate (not illustrated). In this way, the antenna 80b implements a winding coil with a winding number depending on the amount of track lines extending across the hinge region 86b. For example, two track lines extending across the hinge region 86b and connecting the conductive bridging portions 84b and 85b and forming the antenna 80b result in a winding number of one, while four track lines extending across the hinge region 86b and connecting the conductive bridging portions 84b and 85b to form the antenna 80b implies a winding number of two. In general, a number of n track lines (n being an even integer greater zero) extending across the hinge region 86b and connecting the conductive bridging portions 84b and 85b to form the antenna 80b implies a winding number of n/2.

In accordance with some illustrative embodiments and as shown in FIG. 8b, the conductive bridging portions 84b and 85b may be covered by bridge material portions 88b which cover the conductive bridging portions 84b and 85b at least completely across the hinge region 86b, optionally covering portions of the antenna portions 81b and 82b outside the hinge region 86b.

In accordance with some illustrative embodiments herein, the conductive bridging portions 84b and 85b may completely extend across the hinge region 86b and optionally couple to the semicircular antenna portions 81b and 82b outside the hinge region 86b via one or more additional curved routing portions of a substantially semicircular or semi-sinusoidal shape, thereby allowing to elastically compensate mechanical strain acting along a direction perpendicular to the folding line 83b.

In accordance with illustrative embodiments herein and the illustration in FIG. 8b, each of the semicircular antenna portions 81b, 82b is electrically coupled with a respective bridging track line of the conductive bridging portions 84b, 85b such that the antenna 80b having an antenna coil winding structure with at least one winding across the inlay substrate is formed.

With reference to FIG. 8c, a design or layout of an antenna 80c is schematically illustrated in a top view. The antenna 80c comprises semicircular antenna portions 81c and 82c formed on an inlay substrate (not illustrated) at opposing sides of the inlay substrate (not illustrated) relative to a folding line 83c. The antenna portions 81c and 82c each comprise at least one antenna track portion and are electrically coupled by conductive bridging portions 84c and 85c extending across a hinge region 86c of the inlay substrate (not illustrated) which represents a portion of the inlay substrate (not illustrated) that becomes deformed when folding the inlay substrate (not illustrated) along the folding line 83c. The conductive bridging portions 84c and 85c are routed in a sinusoidal manner across the hinge region 86c such that each conductive track line of the conductive bridging portions 84c and 85c extends across the folding line 83c with an inclination angle relative to the folding line 83c different from 90°. In particular, each conductive track line of the conductive bridging portions 84c and 85c may have an inclination angle at the folding line 83c which deviates from the folding line 83c by at most 45° or at most 30° or at most 15° or at most 10°. Accordingly, the conductive bridging portions 84c and 85c substantially become as parallel as possible to the folding line 83c. Additionally or alternatively, the inclination angle of each conductive track line of the conductive bridging portions 84c and 85c at the folding line 83c may deviate from 90° relative to the folding line 83c by at least 1° or at least 5°.

In accordance with some illustrative embodiments, the conductive bridging portions 84c and 85c each comprise at least one conductive track line supplementing the semicircular antenna portions 81c and 82c across the hinge region 86c to form one or more antenna winding on the inlay substrate (not illustrated). In this way, the antenna 80c implements a winding coil with a winding number depending on the amount of track lines extending across the hinge region 86c. For example, two track lines extending across the hinge region 86c and connecting the conductive bridging portions 84c and 85c and forming the antenna 80c result in a winding number of one, while four track lines extending across the hinge region 86c and connecting the conductive bridging portions 84c and 85c to form the antenna 80c implies a winding number of two. In general, a number of n track lines (n being an even integer greater zero) extending across the hinge region 86c and connecting the conductive bridging portions 84c and 85c to form the antenna 80c implies a winding number of n/2.

In accordance with some illustrative embodiments herein, the conductive bridging portions 84c and 85c may completely extend across the hinge region 86c and optionally couple to the semicircular antenna portions 81c and 82c outside the hinge region 86c via one or more additional curved routing portions of a substantially semicircular or semi-sinusoidal shape, thereby allowing to elastically compensate mechanical strain acting along a direction perpendicular to the folding line 83c.

In accordance with illustrative embodiments herein and the illustration in FIG. 8c, each of the semicircular antenna portions 81c, 82c is electrically coupled with a respective bridging track line of the conductive bridging portions 84c, 85c such that the antenna 80c having an antenna coil winding structure with at least one winding across the inlay substrate is formed.

With reference to FIG. 8d, a design or layout of an antenna 80d is schematically illustrated in a top view. The antenna 80d comprises semicircular antenna portions 81d and 82d formed on an inlay substrate (not illustrated) at opposing sides of the inlay substrate (not illustrated) relative to a folding line 83d. The antenna portions 81d and 82d are electrically coupled by conductive bridging portions 84d and 85d extending across a hinge region 86d of the inlay substrate (not illustrated) which represents a portion of the inlay substrate (not illustrated) that becomes deformed when folding the inlay substrate (not illustrated) along the folding line 83d. The conductive bridging portions 84d and 85d are routed in a sinusoidal manner across the hinge region 86d such that each conductive track line of the conductive bridging portions 84d and 85d extends across the folding line 83d with an inclination angle relative to the folding line 83d different from 90°. In particular, each conductive track line of the conductive bridging portions 84d and 85d may have an inclination angle at the folding line 83d which deviates from the folding line 83d by at most 45° or at most 30° or at most 15° or at most 10°. Accordingly, the conductive bridging portions 84d and 85d substantially become as parallel as possible to the folding line 83d. Additionally or alternatively, the inclination angle of each conductive track line of the conductive bridging portions 84d and 85d at the folding line 83d may deviate from 90° relative to the folding line 83d by at least 1° or at least 5°.

In accordance with some illustrative embodiments, the conductive bridging portions 84d and 85d each comprise a plurality of conductive track lines supplementing the semicircular antenna portions 81d and 82d across the hinge region 86d to form plural antenna windings on the inlay substrate (not illustrated). In this way, the antenna 80d implements a winding coil with a winding number depending on the amount of track lines extending across the hinge region 86c. For example, four track lines extending across the hinge region 86d and connecting the conductive bridging portions 84d and 85d and forming the antenna 80d result in a winding number of two, while six track lines extending across the hinge region 86d and connecting the conductive bridging portions 84d and 85d to form the antenna 80d implies a winding number of three. In general, a number of n track lines (n being an even integer greater one) extending across the hinge region 86d and connecting the conductive bridging portions 84d and 85d to form the antenna 80d implies a winding number of n/2.

In accordance with some illustrative embodiments herein, the conductive bridging portions 84d and 85d may completely extend across the hinge region 86d and couple to the semicircular antenna portions 81d and 82d outside the hinge region 86d via distributed routing portions 87d of a shape resembling a diverging bundle of conductive track lines. The diverging bundle represents a transition from a high track line density outside the hinge region 86d towards a sequence of parallel bridging track line portions, each of which having a zig-zag or meander or triangular or sawtooth-like or sinusoidal shape extending across the hinge region 86d.

In accordance with illustrative embodiments herein and the illustration in FIG. 8d, each of the semicircular antenna portions 81d, 82d is electrically coupled with a respective bridging track line of the conductive bridging portions 84d, 85d such that the antenna 80d having an antenna coil winding structure with at least one winding across the inlay substrate is formed.

With reference to FIG. 8e, a design or layout of an antenna 80e is schematically illustrated in a top view. The antenna 80e comprises circular antenna portions 81e and 82e formed on an inlay substrate (not illustrated) at opposing sides of the substrate (not illustrated) relative to a folding line 83e. Each of the antenna portions 81e and 82e forms an antenna coil. The antenna portions 81e and 82e each represent winding coil portions having a dedicated inductance such that the antenna represents a series connection of the antenna portions 81e and 82e. The antenna portions 81e and 82e are electrically coupled by a conductive bridging portion 85e extending across a hinge region 86e of the inlay substrate (not illustrated) which represents a portion of the inlay substrate (not illustrated) that becomes deformed when folding the inlay substrate (not illustrated) along the folding line 83e. The conductive bridging portion 85e is routed linearly at a constant inclination relative to the folding line 83e with an inclination angle different from 90° relative to the folding line 83e. For example, the inclination may deviate from the folding line 83e by at most 45° or at most 30° or at most 15° or at most 10° such that the conductive bridging portion 85e is substantially as parallel as possible to the folding line 83e. Additionally or alternatively, the inclination angle relative to the folding line 83e may deviate from 90° by at least 1° or at least 5°.

In accordance with some illustrative embodiments, the conductive bridging portion 85e comprises at least two conductive track lines so as to supplement the series coupling of the antenna portions 81e and 82e across the hinge region 86e. In this way, the antenna 80e implements an inductance formed of two winding coils with one winding coil having a winding number of at least one and the other winding coil having a winding number of at least two. For example, the antenna portion 81e in the illustration of FIG. 8e has a winding number of at least two such that a u-turn section 89e (a semi-loop resembling a u shape) is provided for allowing a rewinding of turns such that wire track lines are routed back to the hinge region 86e so as to cross the folding line for routing the track line back to the side of the antenna portion 82e, a side where a chip module (not illustrated) is located. An according routing is necessary because the chip module (not illustrated) is commonly arranged on one side of the folding line 83e in order to avoid an overlap of the chip module (not illustrated) with the hinge region 86e.

Although not illustrated in FIG. 8e, the conductive bridging portion 85e may couple to the antenna portions 81e and 82e outside the hinge region 86e via curved routing portions (not illustrated) for elastically compensating mechanical strain acting along a direction perpendicular to the folding line 83e as described.

In accordance with illustrative embodiments herein and the illustration in FIG. 8e, each of the circular antenna portions 81e, 82e is electrically coupled with a respective bridging track line of the conductive bridging portion 85e such that the antenna 80e having an antenna coil winding structure with at least one winding across the inlay substrate is formed.

In accordance with illustrative embodiments herein as described above with respect to at least one of FIGS. 8a to 8e, any of the antennas 80a to 80e may be formed by a plurality of windings, i.e., the number of windings being greater than one. For any of the antennas 80a to 80e, a density of track lines in each semicircular antenna portions 81a, 82a to 81d, 82d and/or the circular antenna portions 81e, 82e may be equal or substantially equal or may be different to a density of track lines of the respective one(s) of the conductive bridging portions 84a, 85a to 84d, 85d and 85e. For example, the densities of track lines in the portions 81a, 82a, 84a, 85a and/or 81b, 82b, 84b, 85b and/or 81c, 82c, 84c, 85c and/or 81d, 82d, 84d, 85d and/or 81e, 82e, 85e may be different such that each portion of the portions 81a, 82a, 84a, 85a and/or 81b, 82b, 84b, 85b and/or 81c, 82c, 84c, 85c and/or 81d, 82d, 84d, 85d and/or 81e, 82e, 85e may have an individual density different from densities in the other portions of the portions 81a, 82a, 84a, 85a and/or 81b, 82b, 84b, 85b and/or 81c, 82c, 84c, 85c and/or 81d, 82d, 84d, 85d and/or 81e, 82e, 85e wherein the densities of track lines in the respective conductive bridging portions 84a, 85a and/or 84b, 85b and/or 84c, 85c and/or 84d, 85d and/or 85e is greater than the densities of track lines in the associated antenna portions 81a, 82a and/or 81b, 82b and/or 81c, 82c and/or 81d, 82d and/or 81e, 82e. According to some special illustrative example herein, the conductive bridging portions 84a, 85a and/or 84b, 85b and/or 84c, 85c and/or 84d, 85d and/or 85e may substantially have a first density of track lines and the semicircular antenna portions 81a, 82a and/or 81b, 82b and/or 81c, 82c and/or 81d, 82d and/or 81e, 82e may substantially have a second density, wherein the first density is greater than the second density. A density of track lines may be defined as a number of track lines extending in a reference area portion, where a reference area portion is an area portion of a specific areal size (e.g., without limitation any area with a size of about 1 mm2) in which neighboring track lines substantially extend linearly in parallel.

In some special illustrative embodiments as discussed above, a density may be equivalently quantized by a pitch of track lines or in other words, a pitch of track lines in a portion of the antenna 80a and/or 80b and/or 80c and/or 80d and/or 80e may be considered as being equivalent to a density of the track lines. Herein, a higher density of track lines is equivalent to a lower pitch of track lines. For example, the pitches of track lines in the portions 81a, 82a, 84a, 85a and/or 81b, 82b, 84b, 85b and/or 81c, 82c, 84c, 85c and/or 81d, 82d, 84d, 85d and/or 81e, 82e, 85e may be different such that each portion of the portions 81a, 82a, 84a, 85a and/or 81b, 82b, 84b, 85b and/or 81c, 82c, 84c, 85c and/or 81d, 82d, 84d, 85d and/or 81e, 82e, 85e may have track lines with an individual pitch of track lines different from pitches of track lines in the other portions of the portions 81a, 82a, 84a, 85a and/or 81b, 82b, 84b, 85b and/or 81c, 82c, 84c, 85c and/or 81d, 82d, 84d, 85d and/or 81e, 82e, 85e, wherein the pitches of track lines in the conductive bridging portions 84a, 85a and/or 84b, 85b and/or 84c, 85c and/or 84d, 85d and/or 85e is smaller than the pitches of track lines in the respective antenna portions 81a, 82a and/or 81b 82b and/or 81c, 82c and/or 81d, 82d and/or 81e, 82e. As an illustrative example, the track lines of the conductive bridging portions 84a, 85a and/or 84b, 85b and/or 84c, 85c and/or 84d, 85d and/or 85e may substantially have a first pitch of track lines and the antenna portions 81a, 82a and/or 81b, 82b and/or 81c, 82c and/or 81d, 82d and/or 81e, 82e may substantially have a second pitch of track lines, wherein the first pitch is smaller than the second pitch. For example, the first pitch may be at most 400 microns and the second pitch may be at least 450 microns or the first pitch may be at most 350 microns and the second pitch may be at least 400 microns or the first pitch may be at most 300 microns and the second pitch may be at least 350 microns or the first pitch may be at most 250 microns and the second pitch may be at least 300 microns.

Accordingly, the track lines of the conductive bridging portions 84a, 85a and/or 84b, 85b and/or 84c, 85c and/or 84d, 85d and/or 85e in any of FIGS. 8a to 8e may absorb a bending force to have a longer fatigue period.

Now referring to FIG. 9, a design or layout of an antenna 90 is schematically illustrated in a top view. The antenna 90 comprises semicircular antenna portions 91 and 92 formed on an inlay substrate (not illustrated) at opposing sides of the substrate (not illustrated) relative to a folding line 93. The antenna portions 91 and 92 each comprise at least one antenna track portion and are electrically coupled by conductive bridging portions 94 and 95. The conductive bridging portions 94 and 95 extend across a hinge region 96 of the inlay substrate (not illustrated) which represents a portion of the inlay substrate (not illustrated) that becomes deformed when folding the inlay substrate (not illustrated) along the folding line 93. The conductive bridging portions 94 and 95 are routed linearly at a constant inclination relative to the folding line 93 with inclination angles α and β different from 90° relative to the folding line 93. For example, the inclination angle α may indicate a deviation from the folding line 93 by at most 45° or at most 30° or at most 25°, e.g., by about 16°. The inclination angle β may indicate a deviation from the folding line 93 by at most 60° or at most 50°, e.g., at about 49°. The deviation from the folding line 93 is such that the conductive bridging portions 94 and 95 are substantially as parallel as possible to the folding line 93. Accordingly, the track lines of the conductive bridging portions 94 and 95 allow to absorb a bending force to have a longer fatigue period.

In accordance with some illustrative embodiments, the conductive bridging portions 94 and 95 may each comprise plural conductive track lines so as to supplement the semicircular antenna portions 91 and 92 across the hinge region 96. Accordingly, each antenna track portion is electrically coupled with a respective conductive track line of the conductive bridging portion 94 and a respective conductive track line of the conductive bridging portion 95. In this way, the antenna 90 implements a winding coil with a winding number depending on the amount of track lines extending across the hinge region 96. For example, two track lines extending across the hinge region 96 and connecting the conductive bridging portions 94 and 95 to form the antenna 90 implies a winding number of one, while four track lines extending across the hinge region 96 and connecting the conductive bridging portions 94 and 95 to form the antenna 90 implies a winding number of two. In general, a number of n track lines (n being an even integer greater zero) extending across the hinge region 96 and connecting the conductive bridging portions 94 and 95 to form the antenna 90 implies a winding number of n/2.

In accordance with some illustrative embodiments and as shown in FIG. 9, the conductive bridging portions 94 and 95 may couple to the semicircular antenna portions 91 and 92 outside the hinge region 96 via curved routing portions 97. In some special illustrative and non-limiting example herein, the curved routing portions 97 may be of a substantially semicircular or semi-sinusoidal shape. The curved routing portions 97 allow to elastically compensate mechanical strain acting along a direction perpendicular to the folding line 93.

With ongoing reference to FIG. 9, the curved portions 97 may represent peaks in a zig zag or triangular or sawtooth shape of the track lines of the conductive bridging portions 94, 95. The peaks may be spaced apart by spacings 97a to 97d from the folding line 93 in the hinge portion 96. The spacings 97a to 97d may be about of equal size. In some special illustrative example, a distance of an antenna curve to the folding line 93 as the center of a spine area of the document may be in the range from about 0.5 mm to about 2 mm, preferably in the range from about 0.5 mm to about 1.5 mm, more preferably in the range from about 0.8 mm to about 1.2 mm, e.g., in the range from about 1.0 mm to about 1.2 mm or in the range from about 1.04 mm to about 1.08 mm such as about 1.06 mm.

In accordance with illustrative embodiments herein and the illustration in FIG. 9, each of the semicircular antenna portions 91, 92 is electrically coupled with a respective bridging track line of the conductive bridging portions 94, 95 such that the antenna 90 having an antenna coil winding structure with at least one winding across the inlay substrate is formed. In illustrative examples herein, where the antenna 90 is formed by a plurality of windings, i.e., the number of windings is greater than one, a density of track lines in each of the semicircular antenna portions 91, 92 and the conductive bridging portions 94, 95 may be equal or substantially equal or may be different. For example, the densities of track lines in the portions 91, 92, 94, 95 may be different such that each portion of the portions 91, 92, 94, 95 may have an individual density different from densities in the other portions of the portions 91, 92, 94, 95 wherein the densities of track lines in the conductive bridging portions 94, 95 is greater than the densities of track lines in the semicircular antenna portions 91, 92. According to some special illustrative example herein, the conductive bridging portions 94, 95 may substantially have a first density of track lines and the semicircular antenna portions 91, 92 may substantially have a second density, wherein the first density is greater than the second density. A density of track lines may be defined as a number of track lines extending in a reference area portion, where a reference area portion is an area portion of a specific areal size (e.g., without limitation any area with a size of about 1 mm2) in which neighboring track lines substantially extend linearly in parallel.

In some special illustrative embodiments as discussed above, a density may be equivalently quantized by a pitch of track lines or in other words, a pitch of track lines in a portion of the antenna 90 may be considered as being equivalent to a density of the track lines. Herein, a higher density of track lines is equivalent to a lower pitch of track lines. For example, the pitches of track lines in the portions 91, 92, 94, 95 may be different such that each portion of the portions 91, 92, 94, 95 may have track lines with an individual pitch of track lines different from pitches of track lines in the other portions of the portions 91, 92, 94, 95, wherein the pitches of track lines in the conductive bridging portions 94, 95 is smaller than the pitches of track lines in the semicircular antenna portions 91, 92. As an illustrative example, the track lines of the conductive bridging portions 94, 95 may substantially have a first pitch of track lines and the semicircular antenna portions 91, 92 may substantially have a second pitch of track lines, wherein the first pitch is smaller than the second pitch. For example, the first pitch may be at most 400 microns and the second pitch may be at least 450 microns or the first pitch may be at most 350 microns and the second pitch may be at least 400 microns or the first pitch may be at most 300 microns and the second pitch may be at least 350 microns or the first pitch may be at most 250 microns and the second pitch may be at least 300 microns.

Although none of the FIGS. 8a and 8c to 8e and 9 shows bridge material portions, this does not impose any limitation on the present disclosure and at least one of the conductive bridging portions shown in FIGS. 8a and 8c to 8e may be covered by bridge material portions which at least completely extend across respective hinge regions, optionally covering portions of antenna portions outside hinge regions.

In accordance with some illustrative embodiments and referring to any of the antennas as described above with regard to FIGS. 1 to 9, antenna portions may be formed by track lines having a thickness of at most 100 μm. It is referred to any of the above described antennas, the disclosure of which is incorporated in its entirety by reference. For example, the thickness of track lines may be in the range from about 1 μm to about 100 μm. The person skilled in the art will appreciate that the upper limit of 100 μm for the thickness of track lines may not be considered as limiting the invention to this thickness. However, in addition to aesthetic reasons according to which it may be desirable to reduce an amount of possible stepping in the surface of an inlay substrate and/or document, it is cost efficient and allows to saves resources when optimizing the thickness of track lines to a thickness range in which a required minimum performance of the antenna is realized, while reducing the amount of materials employed in the preparation and attachment of antenna portions. For example, aside from reducing the amount of material used for preparing antenna portions, an amount of adhesive means used for attaching antenna portions on inlay substrates may be reduced, as well. Furthermore, a risk of unintentional damage of inlay substrates and/or documents due to a stepping of more than 100 μm caused by antenna portions may be reduced. Regarding a lower limit of the thickness of antenna portions, a performance of antenna portions having a thickness of less than 1 μm may not be sufficiently high to ensure a required performance of the antenna portions.

In accordance with some illustrative embodiments and referring to any of the antennas as described above with regard to FIGS. 1 to 9, antenna portions may be provided by at least one of an etched metallic foil, such as a foil made of aluminum, copper and the like, attached to the inlay substrate, a metallic ink printed onto the inlay substrate, such as a silver ink or paste or a wire. It is referred to any of the above-described antennas, the disclosure of which is incorporated in its entirety by reference. In accordance with some special illustrative embodiments, For example, the metallic foil may be attached by means of a heat-activated glue or a cold glue or by means of hot or cold roll lamination techniques. In accordance with some preferred but not limiting examples herein, an aluminum foil may be etched for providing antenna portions, the aluminum foil representing a cost efficient material when compared to other materials employed as conductive coatings used for antennas, such as copper and silver.

In accordance with some special advantageous, but not limiting embodiments of the present disclosure, a metallic foil may be provided by forming a thin layer of metal on a carrier material, such as a PET material. For example, as a metal material for the thin layer of metal, aluminum, copper, silver and the like may be used. Furthermore, the accordingly provided metallic foil may have an optional adhesive layer bonded thereon, such that the metallic foil together with the adhesive layer may be attached on the inlay substrate of any of the antennas as describe above with regard to FIGS. 1 to 9. The attachment may be achieved by means of the adhesive layer and, optionally, the carrier material may be removed after attachment of the metallic foil on the inlay substrate, thereby leaving the thin layer of metal on the inlay substrate attached thereto with the adhesive layer. In case that the carrier layer is not removed, the carrier layer may provide an improved bonding strength to subsequently formed layers on the inlay substrate, e.g., a bridging material.

Although the conductive bridging portions in FIGS. 1 to 7 and 9 are described with respect to a specific embodiment of the antenna, antenna portions, this does not pose any limitation on the present disclosure and the explicitly depicted and described conductive bridging portions in any of FIGS. 1 to 7 and 9 may be replaced by another appropriate conductive bridging portion and/or different types of conductive bridging portions may be mixed in an antenna.

Furthermore, the antennas as described with regard to FIGS. 1 to 7 are depicted and described as realizing a specific antenna design. However, this does not limit the disclosure and the person skilled in the art will appreciate that the antennas as depicted and described in the context of any of FIGS. 1 to 7 and 9 may be replaced by an antenna having the design of layout described above with respect to FIG. 8e. In particular, any of the antennas shown and described in the context of any of FIGS. 1 to 7 and 9 may be instead implemented by an antenna having plural antenna winding coil portions with identical of different winding number.

Although FIG. 8e shows a layout or design of an antenna with two coil winding portions connected in series, this does not provide any limitation and only one coil winding portion may be provided instead. In particular, the antenna 80e of FIG. 8e may be modified such that one of the antenna portions 81e and 82e is omitted. Instead, the remaining one of the antenna portions 81e and 82e on one side of the inlay substrate (not illustrated) relative to the hinge region 86e may be connected via the conductive bridging portions 85e with a chip module (not illustrated) or contact pads (not illustrated) across the folding line 83e. Accordingly, an antenna inlay for a document may be provided, comprising an antenna having a single antenna portion which is routed so as to form an antenna coil providing the antenna with at least one winding. The antenna inlay may further comprises two contact pads (not illustrated) for electrical connection with a chip module (not illustrated) or may be directly connected with the chip module (not illustrated), wherein the antenna portion is electrically coupled with the two contact pads (not illustrated) or the chip module (not illustrated) via a conductive bridging portion.

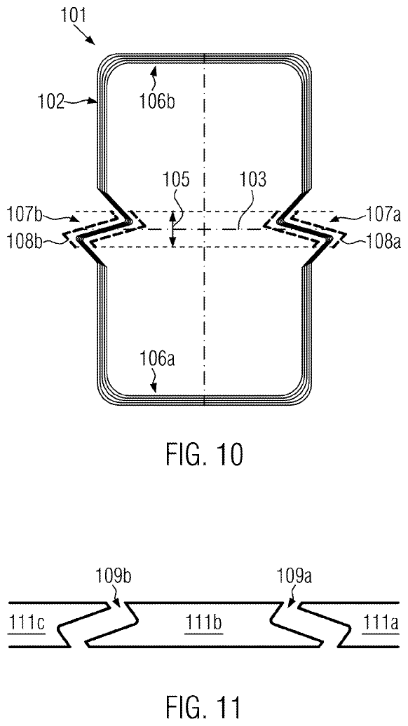

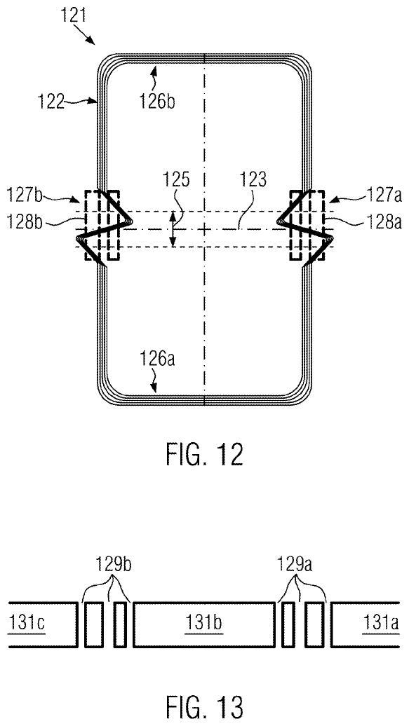

Referring to FIGS. 10 and 11, illustrative embodiments are now described. FIG. 10 shows an antenna inlay 101. The antenna inlay 101 may be provided in a multilayer configuration, comprising an inlay substrate (not illustrated) on which an antenna 102 having semicircular antenna portions 106a and 106b being electrically coupled by conductive bridging portions 107a, 107b are formed. The antenna portions 106a and 106b each comprise at least one antenna track portion. The conductive bridging portions 107a, 107b extend across a folding line 103 along which the antenna inlay 101 is foldable and each of the conductive bridging portions 107a, 107b comprises at least one bridging track line. That is, the antenna inlay 101 may be bend into a curved shape when folding the antenna inlay 101 along the folding line 103 in a hinge region 105. In some illustrative examples, the antenna inlay 101 may be similar to or substantially correspond to the an antenna inlay as described with regard to any of FIGS. 1 to 9 of the present disclosure, the disclosure of which is incorporated in its entirety by reference. Each of the conductive bridging portions 107a, 107b may have one or more bridging track lines routed in a zig-zag or meander-like or triangular or sawtooth relative to the folding line, wherein the zig-zag or meander-like or triangular or sawtooth shape of the folding line is a shape of a curve that resembles a piecewise linear function.

In accordance with some illustrative embodiments, the antenna inlay 101 may further comprise at least one bridge material portion 108a, 108b such that each of the conductive bridging portions 107a, 107b is at least partially covered or embedded into the bridge material portion 108a, 108b. For example, the bridge material portions 108a, 108b may be formed and arranged so as to only at least partially cover a respective one of the conductive bridging portions 107a, 107b while otherwise leaving the antenna inlay 101 substantially uncovered. Accordingly, the antenna inlay 101 in these illustrative embodiments may correspond to document 60 with the antenna inlay 61 in FIG. 7.

In some illustrative embodiments, the bridge material portions 108a, 108b are formed and arranged such that they only at least partially cover a respective one of the conductive bridging portions 107a, 107b, while otherwise leaving the antenna substantially uncovered.

In accordance with some alternative embodiments to the illustrative embodiments of the preceding paragraph, the antenna inlay 101 may comprise a bridging substrate (not illustrated in FIG. 10) almost completely covering the antenna inlay 101 for completely overlaying the antenna 102, wherein bridge material portions 111a, 111b, 111c (see FIG. 11) are defined in the bridging substrate (not illustrated) by lateral cutout gaps which are formed as zig-zag or meander-like or triangular or sawtooth or sinusoidal shaped cutouts 109a, 109b aligned with the folding line 103 and matching a routing shape of the conductive bridging portion 107a, 107b and aligned therewith. Herein, only the inlay substrate (not illustrated) is partially exposed along the folding line 103 by the cutout gaps 109a, 109b, while the bridge material portions 111a, 111b, 111c cover the antenna inlay 101 outside the cutout gaps 109a, 109b in FIG. 11 as indicated by the broken lines 108a, 108b in FIG. 10. Accordingly, the antenna inlay 101 in these illustrative embodiments may correspond to document 40 with the antenna inlay 41 in FIG. 6.

Referring to FIGS. 12 and 13, further illustrative embodiments are now described. FIG. 12 shows an antenna inlay 121. The antenna inlay 121 may be provided in a multilayer configuration, comprising an inlay substrate (not illustrated) on which an antenna 122 having semicircular antenna portions 126a and 126b being electrically coupled by conductive bridging portions 127a, 127b are formed. The antenna portions 126a and 126b each comprise at least one antenna track portion. The conductive bridging portions 127a, 127b extend across a folding line 123 along which the antenna inlay 121 is foldable and each of the conductive bridging portions 127a, 127b comprises at least one bridging track line. That is, the antenna inlay 121 may be bend into a curved shape when folding the antenna inlay 121 along the folding line 123 in a hinge region 125. The antenna inlay 121 may be similar to or substantially correspond to the an antenna inlay as described with regard to any of FIGS. 1 to 9 of the present disclosure, the disclosure of which is incorporated in its entirety by reference. Each of the conductive bridging portions 127a, 127b may have one or more bridging track lines routed in a zig-zag or meander-like or triangular or sawtooth relative to the folding line, wherein the zig-zag or meander-like or triangular or sawtooth shape of the folding line is a shape of a curve that resembles a piecewise linear function.

In accordance with some illustrative embodiments, the antenna inlay 121 may further comprise at least one bridge material portion 128a, 128b such that each of the conductive bridging portions 127a, 127b is at least partially covered or embedded into the bridge material portion 128a, 128b. For example, the bridge material portions 128a, 128b may be formed and arranged so as to only at least partially cover a respective one of the conductive bridging portions 127a, 127b while otherwise leaving the antenna inlay 121 substantially uncovered. Accordingly, the antenna inlay 121 in these illustrative embodiments may correspond to document 60 with the antenna inlay 61 in FIG. 7.

In some illustrative embodiments, the bridge material portions 128a, 128b are formed and arranged such that they only at least partially cover a respective one of the conductive bridging portions 127a, 127b, while otherwise leaving the antenna substantially uncovered.

In accordance with some alternative embodiments to the illustrative embodiments of the preceding paragraph, the antenna inlay 121 may comprise a bridging substrate (not illustrated in FIG. 13) almost completely covering the antenna inlay 121 for completely overlaying the antenna 102, wherein bridge material portions 131a, 131b, 131c (see FIG. 13) are defined in the bridging substrate (not illustrated) by lateral cutout gaps which are formed as strip shaped cutouts 129a, 129b aligned with the folding line 123 such that the conductive bridging portion 127a, 127b are partially covered and partially exposed as indicated by the broken lines in FIG. 13. Accordingly, the antenna inlay 121 in these illustrative embodiments may correspond to document 40 with the antenna inlay 41 in FIG. 6.

The embodiments as described with regard to any of FIGS. 10 to 13 may be implemented such that the bridge material portions 88b as shown in FIG. 8b may be provided in accordance with any of the bridge material portions disclosed in the antenna inlays 101 and 121 as described above with regard to FIGS. 10 to 13 for appropriately combining the disclosures of FIG. 8b and FIGS. 10 to 13.

In some special illustrative example of the various embodiments disclosed above, a document may represent a foldable document carrying electronic information, such as a foldable identity document booklet like a passport or the like.

Any approximation as inferred by an approximating term, such as “about” and “substantially” and the like, may be understood as indicating a fault tolerance or a tolerable deviation, variation and/or modification, e.g., without limitation an error of 15% or 10% or 5%.

1. Antenna inlay for a document, comprising:
an inlay substrate foldable along a folding line;
an antenna formed on or embedded into the inlay substrate; and
a bridging substrate almost completely covering the inlay substrate for completely overlaying the antenna, wherein at least one bridge material portion is defined in the bridging substrate by lateral cutout gaps along the folding line,
wherein the antenna comprises a first antenna portion routed outside the folding line and at least one conductive bridging portion routed to extend across the folding line,
wherein the at least one conductive bridging portion is electrically connected with the first antenna portion,
wherein the at least one conductive bridging portion is routed at the folding line so as to cross the folding line at an inclination angle unequal to 90°,
wherein the at least one conductive bridging portion is routed in a zig-zag or meander-like or triangular or sawtooth or sinusoidal shape relative to the folding line, and
wherein the lateral cutout gaps are formed as zig-zag or meander-like or triangular or sawtooth or sinusoidal shaped cutouts matching a routing shape of the at least one conductive bridging portion and aligned therewith.

2. (canceled)

3. (canceled)

4. Antenna inlay of claim 1, the antenna further comprising a second antenna portion routed outside the folding line, wherein the first and second antenna portions are located on opposite sides of the inlay substrate relative to the folding line, and wherein the at least one conductive bridging portion is routed so as to electrically interconnect the first and second antenna portions.

5. Antenna inlay of claim 4, wherein the first antenna portion is routed so as to form a first coil winding portion with a first number of windings greater than or equal to one and the second antenna portion is routed so as to form a second coil winding portion with a second number of windings greater than or equal to two, the first and second coil winding portions being connected by the at least one conductive bridging portion in a series connection.

6. Antenna inlay of claim 5, wherein the first and second coil winding portions are formed with equal winding orientation in an open condition of the antenna inlay and with opposite winding orientation in a closed condition of the antenna inlay.

7. Antenna inlay of claim 5, wherein the first and second coil winding portions are formed with opposite winding orientation in an open condition and with equal winding orientation in a closed condition.

8. Antenna inlay of claim 5, wherein the first and second coil winding portions have equal size and shape.

9. Antenna inlay of claim 4, wherein the first and second antenna portions are connected by the at least one conductive bridging portion so as to form an antenna coil winding with a number of windings greater than or equal to one.

10. Antenna inlay of claim 1, wherein the first antenna portion is routed so as to form an antenna coil providing an antenna with at least one winding and the antenna inlay further comprises a chip module or two contact pads for electrical connection with the chip module, wherein the antenna is electrically coupled with the chip module or the two contact pads via the at least one conductive bridging portion.

11. Antenna inlay of claim 1, further comprising an RF chip module electrically coupled with the antenna.

12. Antenna inlay of claim 11, wherein the RF chip module comprises an integrated circuit chip with contact terminals, the contact terminals being connected to the antenna.

13. Antenna inlay of claim 1, wherein the antenna is formed of a conductive material, e.g., aluminum and/or copper and/or silver and/or a metal alloy material and/or a conductive foil laminated with an insulated layer and/or a wire and/or a conductive ink.

14. (canceled)

15. (canceled)

16. (canceled)

17. Antenna inlay of claim 1, further comprising a bridging substrate almost completely covering the inlay substrate for completely overlaying the antenna, wherein at least one bridge material portion is defined in the bridging substrate by lateral cutout gaps along the folding line, the lateral cutout gaps being formed as zig-zag or meander-like or triangular or sawtooth or sinusoidal shaped cutouts matching a routing shape of the at least one conductive bridging portion and aligned therewith.

18. Antenna inlay of claim 1, wherein the inclination angle at the folding line deviates from 90° by at least 1° or 5°.

19. Antenna inlay of claim 1, wherein track lines of the conductive bridging portion have a first density of track lines and track lines of the first antenna portion have a second density of track lines, the first density of track lines being greater than the second density of track lines.

20. Antenna inlay of claim 1, wherein track lines of the conductive bridging portion have a first pitch of track lines and track lines of the first antenna portion have a second pitch of track lines, the first pitch of track lines being smaller than the second pitch of track lines.

21. Document having the antenna inlay of claim 1 and a foldable document base with a hinge region having a folding line, wherein the antenna inlay is mechanically coupled with the document base such that the folding lines of the document base and the antenna inlay substantially coincide.

22. Document of claim 21, wherein the conductive bridging portion completely extends across the hinge region.

23. Document of claim 21, wherein the document is a booklet having a booklet cover formed by the first and second pages and one or more additional pages connected to the hinge region, the one or more pages being enclosed by the booklet cover.
